(19) United States
(12) Patent Application Publication
(10) Pub. No.: US 2021/0280722 A1
(43) Pub. Date: Sep. 9, 2021

(54) STRAINED SILICON TRANSISTOR

(71) Applicant: QUALCOMM Incorporated, San Diego, CA (US)

(72) Inventors: Haining YANG, San Diego, CA (US); Bin YANG, San Diego, CA (US); Xia LI, San Diego, CA (US)

(21) Appl. No.: 16/809,534

(22) Filed: Mar. 4, 2020

(51) Int. Cl. H01L 29/786; H01L 27/092; H01L 29/06; H01L 29/423; H01L 21/02; H01L 21/306; H01L 21/308; H01L 21/8238; H01L 29/66

(52) U.S. Cl. CPC H01L 29/78696; H01L 29/66742; H01L 29/0673; H01L 29/42392; H01L 29/78651; H01L 29/78684; H01L 21/0217; H01L 21/02603; H01L 21/02532; H01L 21/30604; H01L 21/308; H01L 21/823807; H01L 21/823814; H01L 21/823828; H01L 21/823878; H01L 29/66545; H01L 27/092

(57) ABSTRACT

Strained silicon transistor, such as GAA transistors, allow for both good PMOS mobility and NMOS mobility on the same substrate. In one example, a GAA circuit may include a NMOS device on a tensile strained Si channel and a PMOS device on a compressive strained SiGe channel. In another example, a GAA circuit may include a NMOS device on a strained Si channel and a PMOS device on a relaxed SiGe channel on (110) crystalline substrate.

### FIELD OF DISCLOSURE

This disclosure relates generally to transistors, and more specifically, but not exclusively, to strain silicon transistors.

### BACKGROUND

Semiconductor transistors have scaled from planar transistors to finfets, and are expected to migrate to nano-sheet transistors devices after 5 nm nodes become standard. Due to excellent electronic and mechanical properties, monocrystalline silicon (Si) has become the dominant substrate and structural material in such integrated circuits and devices. Monocrystalline silicon has three typical crystal planes or surfaces, i.e., (100), (110) and (111). Based on anisotropic surface properties of silicon wafers with different plane orientations, these wafers were employed as substrate material in manufacturing transistors. For example, Si (100) is used in complementary metal oxide semiconductor (CMOS) because of the lowest interfacial state and least fixed charge. In addition, Si (110) is often used as the substrate surface to grow low-dimensional structures such as nanowires.

The two top transistors for 5 nm and smaller nodes have emerged, finfets and gate all around (GAA) (also known as surrounding gate transistors (SGT)) transistors. GAA devices provide an advantage over finfet devices with improved short channel effect, channel length reduction, and gate pitch reduction. GAA devices may also increase drive current with larger effective device widths while the GAA device drive strength (or effective width) can be adjusted by changing the nano-sheet width. However, GAA NMOS and PMOS devices are on same silicon (Si) surf substrate ace, resulting in one device having low mobility/performance while the other device is better. For example, the PMOS mobility is worst on a (100) substrate, while the NMOS mobility is the best, and the PMOS mobility is best on a (110) substrate, while the NMOS mobility is the worst.

Accordingly, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a transistor circuit may comprise: a first transistor with a silicon channel; and a second transistor with a silicon germanium channel.

In another aspect, a transistor circuit may comprise: first means for amplifying or switching on a silicon channel; and second means for amplifying or switching on a silicon germanium channel.

In still another aspect, a transistor circuit may comprise: a NMOS transistor on a silicon channel; and a PMOS transistor on a silicon germanium channel.

In still another aspect, a method of manufacturing a transistor circuit may comprises: providing a substrate; forming a plurality of alternative epitaxial layers of silicon and silicon germanium; forming a shallow trench insolation region; forming a dummy gate; depositing a gate spacer; etching the gate spacer; etching a PMOS region; etching the silicon germanium layers to form recessed regions; forming a plurality of spacers in the recessed regions; forming a source region and a drain region for the PMOS region; forming a NMOS spacer; and forming a source region and a drain region for an NMOS region.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary transistor circuit in accordance with some examples of the disclosure;

FIG. 2 illustrates an exemplary side view of a transistor circuit in accordance with some examples of the disclosure;

FIG. 3 illustrates an exemplary side view of a transistor circuit in accordance with some examples of the disclosure;

FIG. 4 illustrates an exemplary transistor circuit in accordance with some examples of the disclosure;

FIG. 5 illustrates an exemplary side view of a transistor circuit in accordance with some examples of the disclosure;

FIG. 6 illustrates an exemplary side view of a transistor circuit in accordance with some examples of the disclosure;

FIGS. 7-13 illustrate an exemplary an exemplary partial method for manufacturing a transistor circuit in accordance with some examples of the disclosure;

FIG. 14 illustrates an exemplary partial method for manufacturing a transistor circuit in accordance with some examples of the disclosure;

FIG. 15 illustrates an exemplary mobile device in accordance with some examples of the disclosure; and

FIG. 16 illustrates various electronic devices that may be integrated with any of the aforementioned methods, devices, semiconductor devices, integrated circuits, die, interposers, packages, or package-on-packages (PoPs) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs. Examples herein include strained silicon transistors, such as GAA transistors, that allow for both good PMOS mobility and NMOS mobility on the same substrate. In one example, a GAA circuit may include a NMOS device on a tensile strained Si channel and a PMOS device on a compressive strained SiGe channel. In another example, a GAA circuit may include a NMOS device on a strained Si channel and a PMOS device on a relaxed SiGe channel on (110) crystalline substrate. Such strained silicon transistor devices provide many benefits over conventional approaches include, but not limited to, enhanced NMOS mobility with tensile strain from a SiGe or Ge substrate, improved PMOS mobility from a compressive strained SiGe channel, and improved PMOS mobility due to a SiGe channel on (110) substrate.

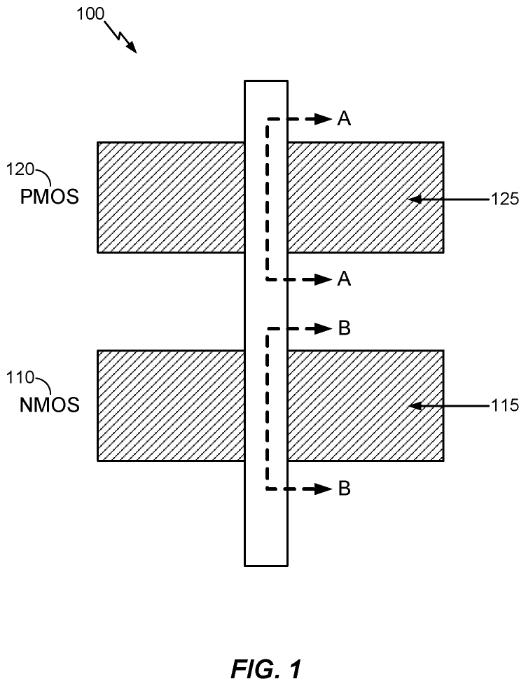

FIG. 1 illustrates an exemplary transistor circuit in accordance with some examples of the disclosure. As shown in FIG. 1, a transistor circuit 100 may include a first transistor 110 (e.g., a NMOS transistor) on a silicon germanium (SiGe) substrate 115 with a middle to low germanium percentage (i.e., less than 50 percent) and a second transistor 120 on a SiGe substrate 125 with a middle to low germanium percentage.

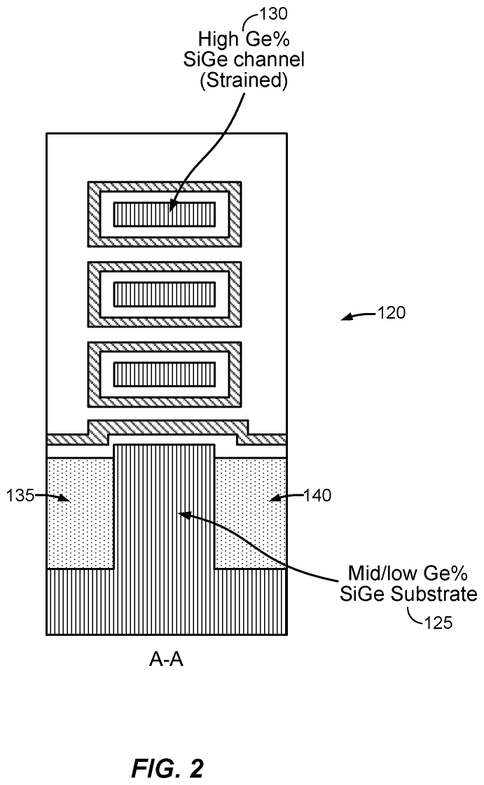

FIG. 2 illustrates an exemplary side view of a transistor circuit in accordance with some examples of the disclosure. As shown in FIG. 2, the second transistor 120 may include a silicon germanium channel 130, a source region 135, and a drain region 140 on the SiGe substrate 125.

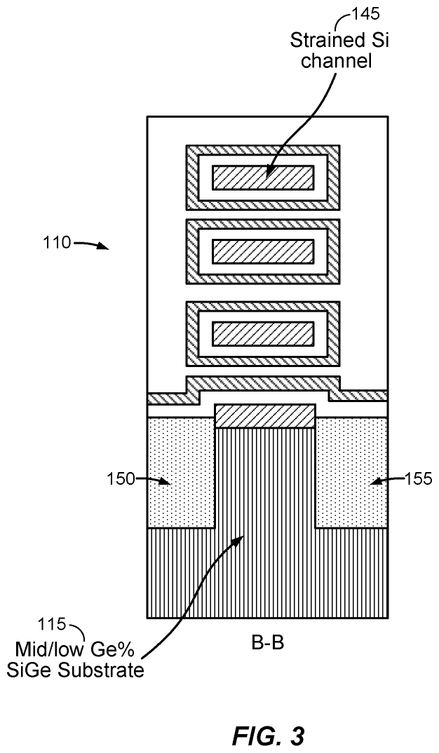

FIG. 3 illustrates an exemplary side view of a transistor circuit in accordance with some examples of the disclosure. As shown in FIG. 2, the first transistor 110 may include a silicon channel 145, a source region 155, and a drain region 150 on the SiGe substrate 115.

It should be understood that while shown in one configuration in FIGS. 1-3, alternative configurations are available, such as: the silicon channel 145 is a strained silicon channel, such as by tensile straining; the silicon germanium channel 130 is a strained channel, such as by compressive straining; the silicon germanium channel 130 is a relaxed silicon germanium channel, and/or the silicon germanium channel 130 is on a 110 substrate. Strained silicon is a layer of silicon in which the spacing between silicon atoms are stretched or compressed beyond their normal interatomic distance. This can be accomplished by putting the layer of silicon over a substrate of silicon germanium

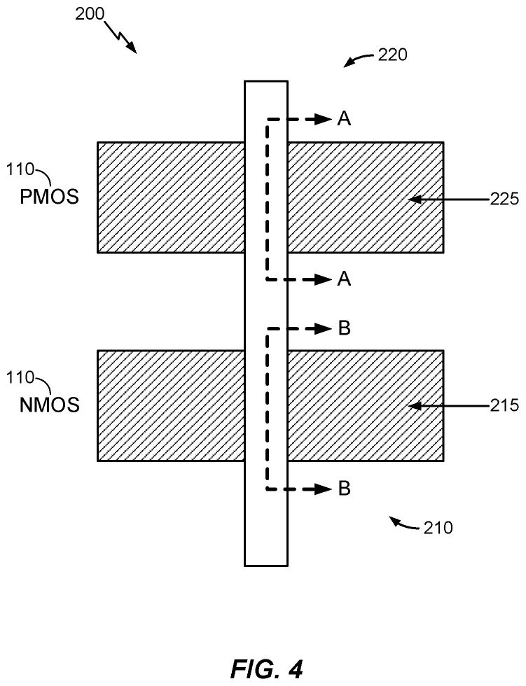

FIG. 4 illustrates an exemplary transistor circuit in accordance with some examples of the disclosure. As shown in FIG. 4, a transistor circuit 200 may include a first transistor 210 (e.g., a NMOS transistor) on a SiGe or germanium substrate 215 with a 110 surface and a second transistor 220 on a SiGe or germanium substrate 225 with a 110 surface.

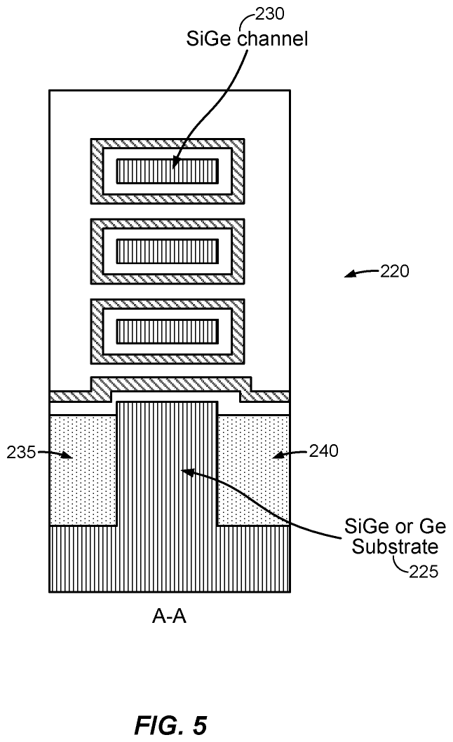

FIG. 5 illustrates an exemplary side view of a transistor circuit in accordance with some examples of the disclosure. As shown in FIG. 5, the second transistor 220 may include a silicon germanium channel 230, a source region 235, and a drain region 240 on the SiGe or Ge substrate 225.

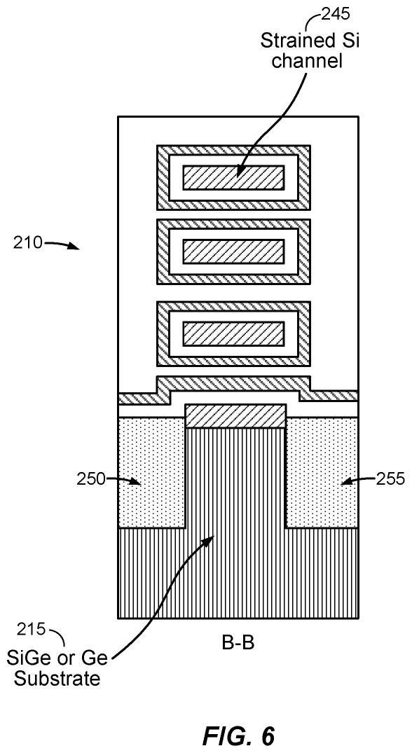

FIG. 6 illustrates an exemplary side view of a transistor circuit in accordance with some examples of the disclosure. As shown in FIG. 2, the first transistor 210 may include a silicon channel 245, a source region 255, and a drain region 250 on the SiGe or Ge substrate 215.

It should be understood that while shown in one configuration in FIGS. 4-6, alternative configurations are available, such as: the silicon channel 245 is a strained silicon channel, such as by tensile straining; the silicon channel 145 is on a 110 substrate; the silicon germanium channel 230 is a strained channel, such as by compressive straining; the silicon germanium channel 230 is a relaxed silicon germanium channel; and/or the silicon germanium channel 230 is a on a 110 substrate.

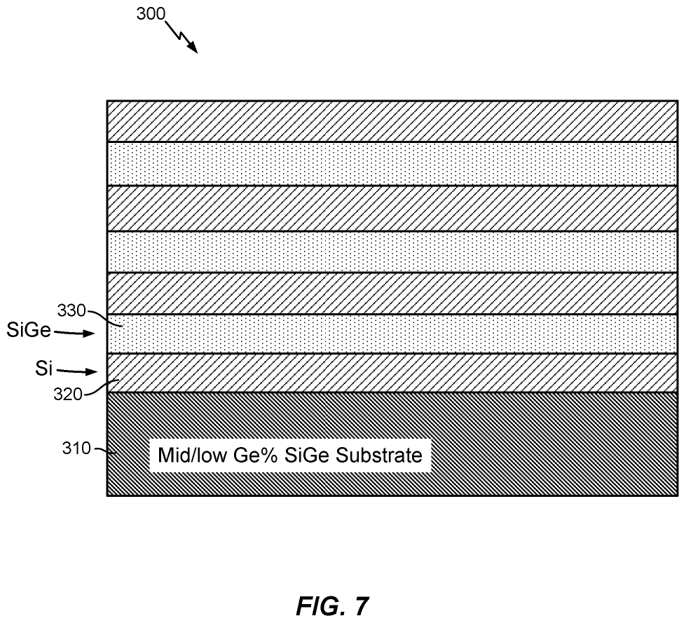

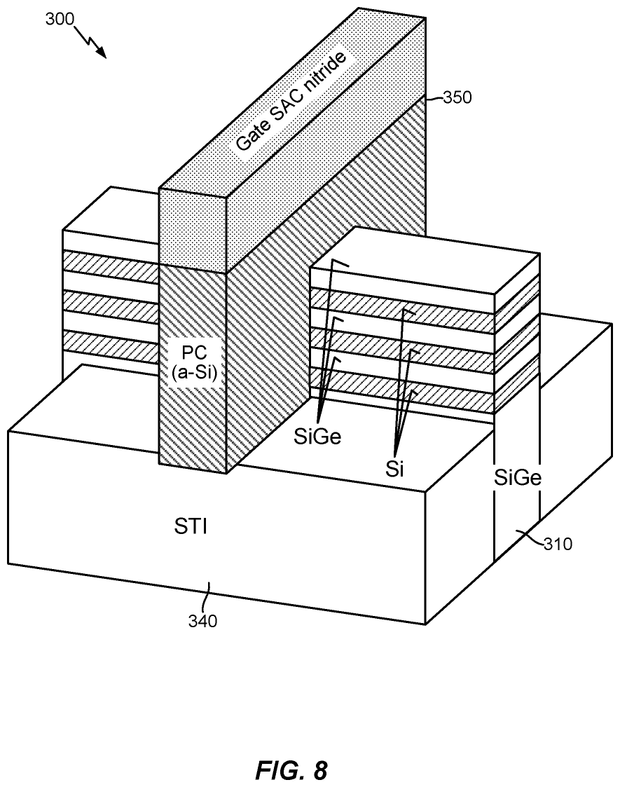

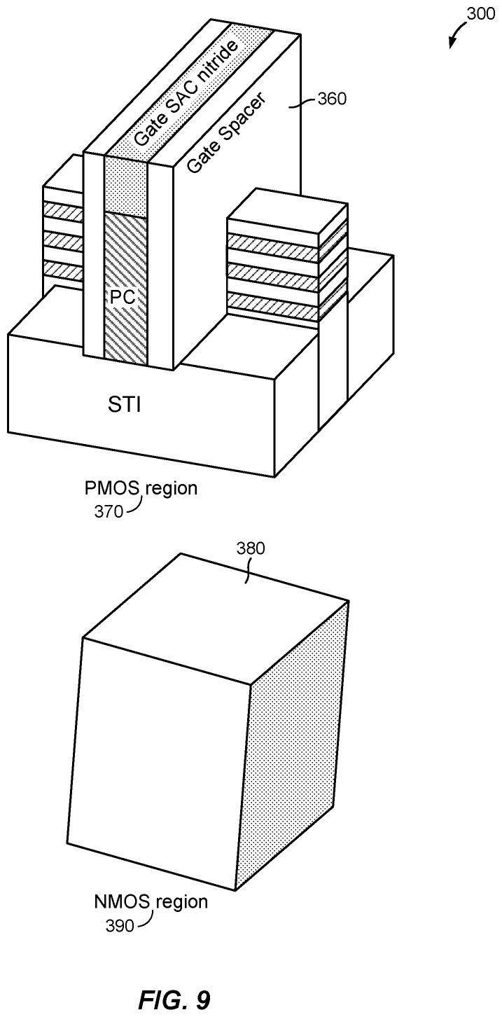

FIGS. 7-13 illustrate an exemplary an exemplary partial method for manufacturing a transistor circuit in accordance with some examples of the disclosure. As shown in FIG. 7, the partial method 300 may begin with a SiGe substrate having a middle to low Ge concentration and epitaxially grown alternating layers of Si 320 and SiGe 330. The partial method 300 continues in FIG. 8 with active patterning including forming a shallow trench isolation region 340 and forming a dummy gate 350. The partial method 300 continues in FIG. 9 with depositing a gate spacer 360 for a PMOS region 370 and etching the gate spacer 360 while masking 380 a NMOS region 390.

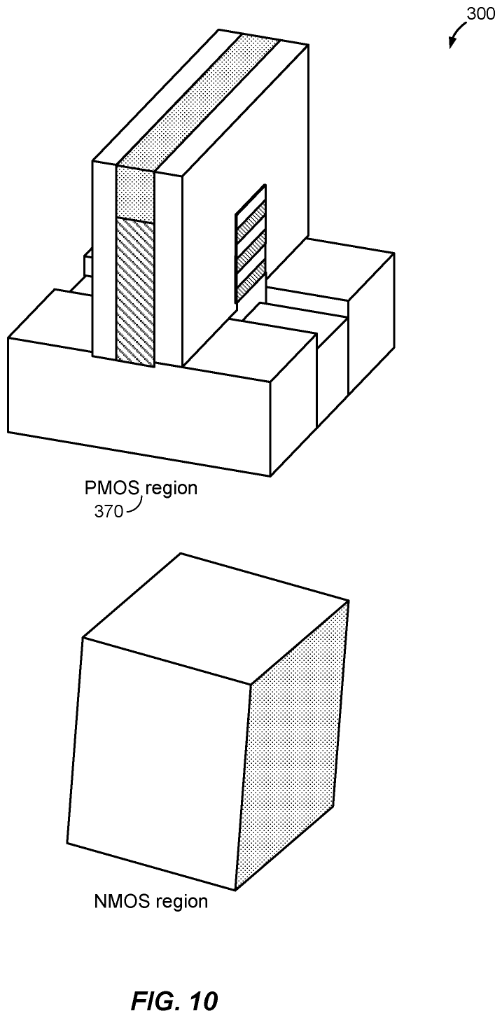

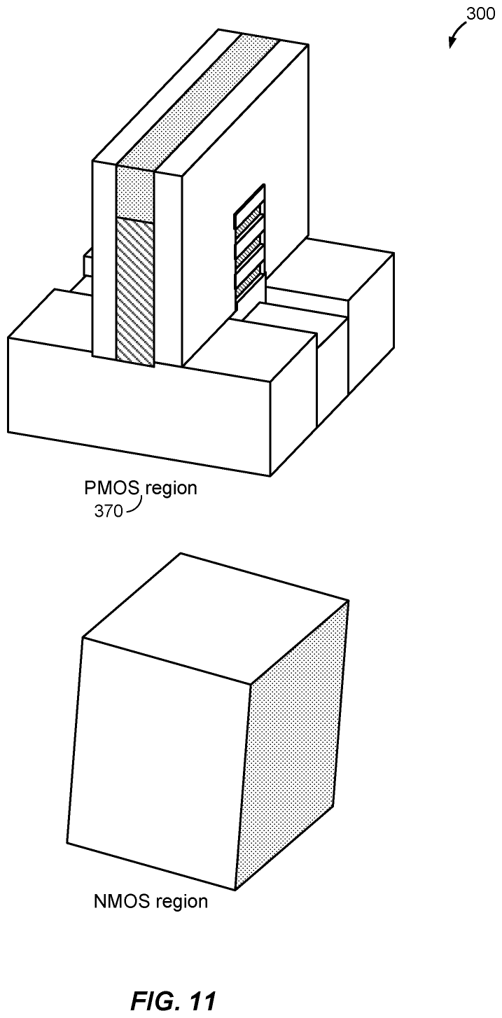

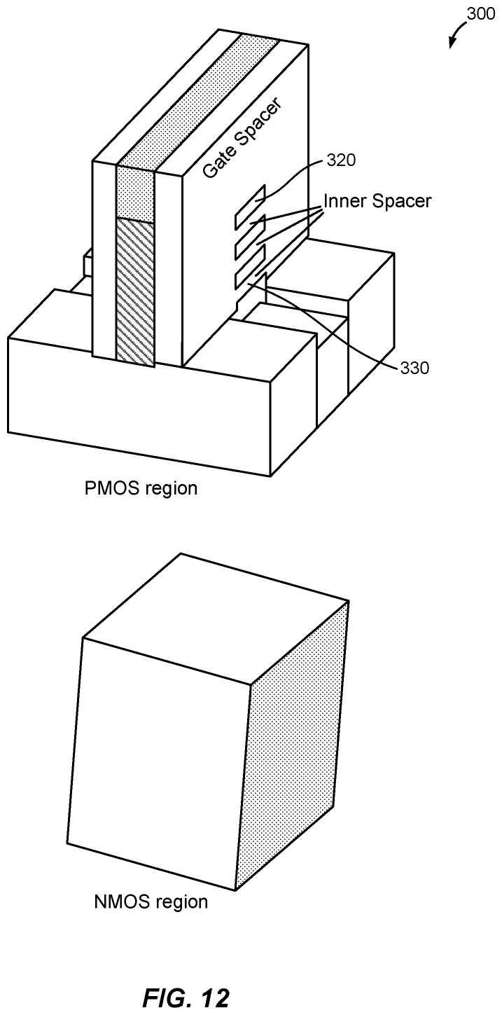

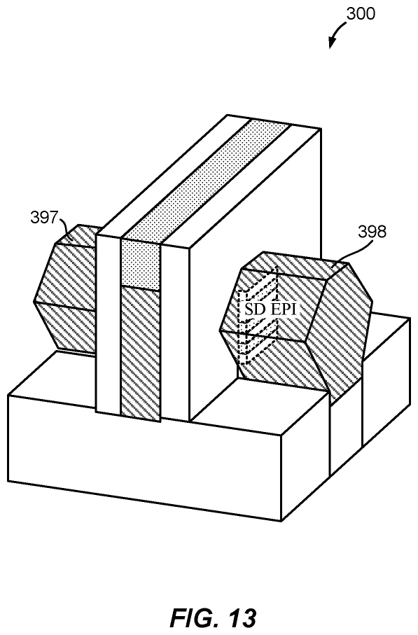

The partial method 300 continues in FIG. 10 with etching the PMOS region 370. The partial method 300 continues in FIG. 11 with etching the silicon germanium layers 330 (and etching the silicon layers 320) to form recessed regions. The partial method 300 continues in FIG. 12 with forming a plurality of spacers 395 in the recessed regions. The partial method 300 may conclude in FIG. 13 with forming a NMOS spacer (not shown), and forming a source region 397 and a drain region 398.

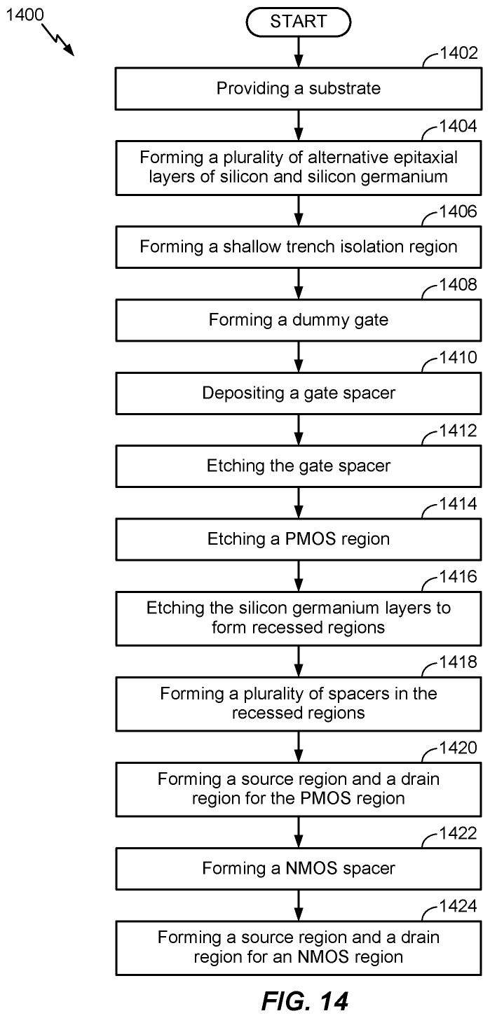

FIG. 14 illustrates an exemplary partial method for manufacturing a transistor circuit in accordance with some examples of the disclosure. As shown in FIG. 14, the partial method 1400 may begin in block 1402 with providing a substrate. The partial method 1400 may continue in block 1404 with forming a plurality of alternative epitaxial layers of silicon and silicon germanium. The partial method 1400 may continue in block 1406 with forming a shallow trench insolation region. The partial method 1400 may continue in block 1408 with forming a dummy gate. The partial method 1400 may continue in block 1410 with depositing a gate spacer. The partial method 1400 may continue in block 1412 with etching a PMOS spacer. The partial method 1400 may continue in block 1414 with etching a PMOS region. The partial method 1400 may continue in block 1416 with etching the silicon germanium layers to form recessed regions. The partial method 1400 may continue in block 1418 with forming a plurality of spacers in the recessed regions. The partial method 1400 may continue in block 1420 with forming a source region and a drain region for the PMOS region. The partial method 1400 may continue in block 1422 with forming a NMOS spacer. The partial method 1400 may conclude in block 1424 with forming a source region and a drain region for an NMOS region.

Alternatively, the partial method 1400 may include depositing a silicon nitride film before forming the shallow trench isolation region; masking an NMOS region before etching the PMOS spacer; wherein the source region and the drain region for the PMOS region and the NMOS region are epitaxial grown, and incorporating the transistor circuit into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

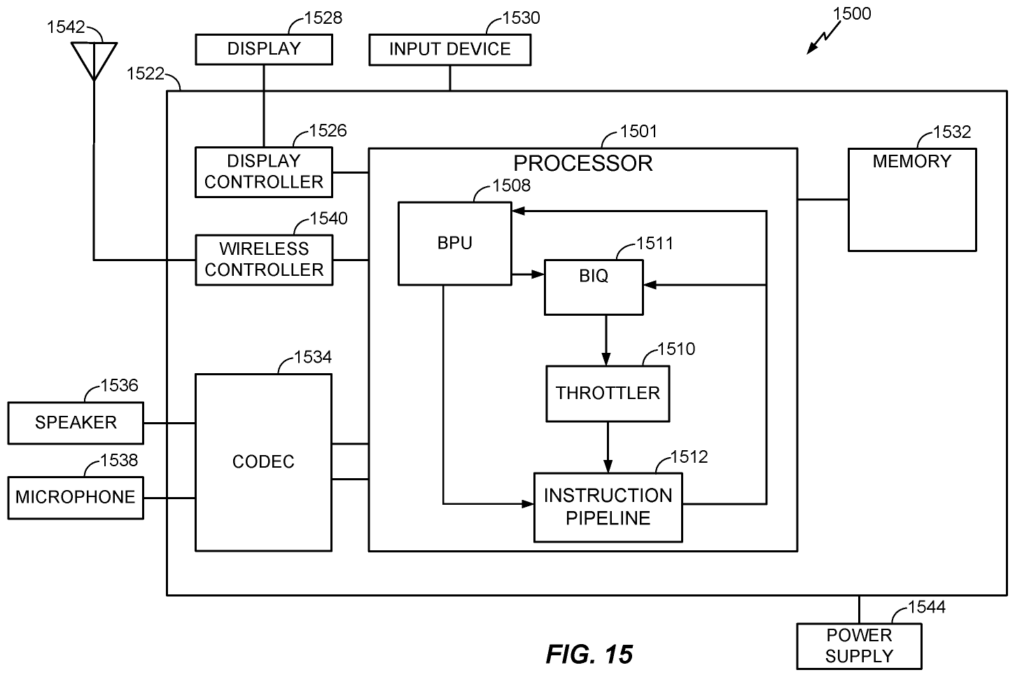

FIG. 15 illustrates an exemplary mobile device in accordance with some examples of the disclosure. Referring now to FIG. 15, a block diagram of a mobile device that is configured according to exemplary aspects is depicted and generally designated 1500. In some aspects, mobile device 1500 may be configured as a wireless communication device. As shown, mobile device 1500 includes processor 1501, which may be configured to implement the methods described herein in some aspects. Processor 1501 is shown to comprise instruction pipeline 1512, buffer processing unit (BPU) 1508, branch instruction queue (BIQ) 1511, and throttler 1510 as is well known in the art. Other well-known details (e.g., counters, entries, confidence fields, weighted sum, comparator, etc.) of these blocks have been omitted from this view of processor 1501 for the sake of clarity.

Processor 1501 may be communicatively coupled to memory 1532 over a link, which may be a die-to-die or chip-to-chip link. Mobile device 1500 also include display 1528 and display controller 1526, with display controller 1526 coupled to processor 1501 and to display 1528.

In some aspects, FIG. 15 may include coder/decoder (CODEC) 1534 (e.g., an audio and/or voice CODEC) coupled to processor 1501; speaker 1536 and microphone 1538 coupled to CODEC 1534; and wireless controller 1540 (which may include a modem) coupled to wireless antenna 1542 and to processor 1501.

In a particular aspect, where one or more of the above-mentioned blocks are present, processor 1501, display controller 1526, memory 1532, CODEC 1534, and wireless controller 1540 can be included in a system-in-package or system-on-chip device 1522. Input device 1530 (e.g., physical or virtual keyboard), power supply 1544 (e.g., battery), display 1528, input device 1530, speaker 1536, microphone 1538, wireless antenna 1542, and power supply 1544 may be external to system-on-chip device 1522 and may be coupled to a component of system-on-chip device 1522, such as an interface or a controller.

It should be noted that although FIG. 15 depicts a mobile device, processor 1501 and memory 1532 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

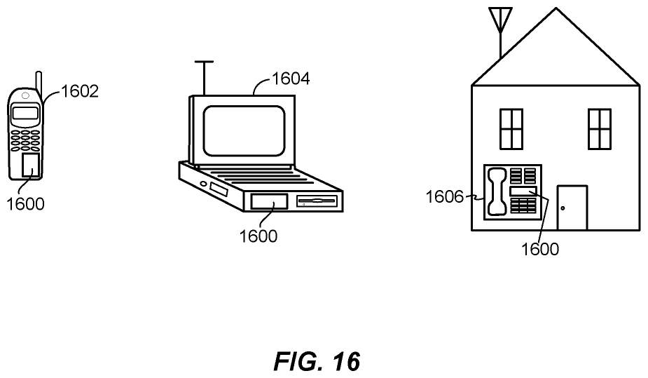

FIG. 16 illustrates various electronic devices that may be integrated with any of the aforementioned integrated device, semiconductor device, integrated circuit, die, interposer, package or package-on-package (PoP) in accordance with some examples of the disclosure. For example, a mobile phone device 1602, a laptop computer device 1604, and a fixed location terminal device 1606 may include an integrated device 1600 as described herein. The integrated device 1600 may be, for example, any of the integrated circuits, dies, integrated devices, integrated device packages, integrated circuit devices, device packages, integrated circuit (IC) packages, package-on-package devices described herein. The devices 1602, 1604, 1606 illustrated in FIG. 16 are merely exemplary. Other electronic devices may also feature the integrated device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

It will be appreciated that various aspects disclosed herein can be described as functional equivalents to the structures, materials and/or devices described and/or recognized by those skilled in the art. It should furthermore be noted that methods, systems, and apparatus disclosed in the description or in the claims can be implemented by a device comprising means for performing the respective actions of this method. For example, in one aspect, a transistor circuit may include: first means for amplifying or switching (e.g., a transistor, such as a NMOS transistor) on a silicon channel; and second means for amplifying or switching (e.g., a transistor, such as a PMOS transistor) on a silicon germanium channel. Furthermore the first means for amplifying or switching may be a NMOS transistor and the silicon channel may be a strained silicon channel, and the second means for amplifying or switching is a PMOS transistor and the silicon germanium channel is a strained channel. It will be appreciated that the aforementioned aspects are merely provided as examples and the various aspects claimed are not limited to the specific references and/or illustrations cited as examples.

One or more of the components, processes, features, and/or functions illustrated in FIGS. 1-16 may be rearranged and/or combined into a single component, process, feature or function or incorporated in several components, processes, or functions. Additional elements, components, processes, and/or functions may also be added without departing from the disclosure. It should also be noted that FIGS. 1-16 and its corresponding description in the present disclosure is not limited to dies and/or ICs. In some implementations, FIGS. 1-16 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package on package (PoP) device, and/or an interposer. An active side of a device, such as a die, is the part of the device that contains the active components of the device (e.g. transistors, resistors, capacitors, inductors etc.), which perform the operation or function of the device. The backside of a device is the side of the device opposite the active side.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5 (both expressly incorporated herein in their entirety).

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or other such configurations). Additionally, these sequence of actions described herein can be considered to be incorporated entirely within any form of computer-readable storage medium (transitory and non-transitory) having stored therein a corresponding set of computer instructions that upon execution would cause an associated processor to perform the functionality described herein. Thus, the various aspects of the disclosure may be incorporated in a number of different forms, all of which have been contemplated to be within the scope of the claimed subject matter. In addition, for each of the examples described herein, the corresponding form of any such examples may be described herein as, for example, “logic configured to” perform the described action.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Further, those of skill in the art will appreciate that the various illustrative logical blocks, modules, circuits, and algorithm actions described in connection with the examples disclosed herein may be implemented as electronic hardware, computer software, or combinations of both. To clearly illustrate this interchangeability of hardware and software, various illustrative components, blocks, modules, circuits, and actions have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be incorporated directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art including non-transitory types of memory or storage mediums. An exemplary storage medium is coupled to the processor such that the processor can read information from, and write information to, the storage medium. In the alternative, the storage medium may be integral to the processor.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A transistor circuit comprising:
a first transistor comprising a silicon channel; and
a second transistor comprising a silicon germanium channel.

2. The transistor circuit of claim 1, wherein the first transistor is a NMOS transistor and the silicon channel is a strained silicon channel.

3. The transistor circuit of claim 2, wherein the strained silicon channel is a tensile strained silicon channel.

4. The transistor circuit of claim 1, wherein the second transistor is a PMOS transistor and the silicon germanium channel is a strained channel.

5. The transistor circuit of claim 4, wherein the strained silicon germanium channel is a compressive strained silicon germanium channel.

6. The transistor circuit of claim 1, wherein the silicon channel is a strained silicon channel and the silicon germanium channel is a relaxed silicon germanium channel.

7. The transistor circuit of claim 1, wherein the silicon germanium channel is a on a 110 substrate.

8. The transistor circuit of claim 7, wherein the silicon germanium channel is a relaxed silicon germanium channel.

9. The transistor circuit of claim 1, wherein the first transistor is a NMOS transistor and the second transistor is a PMOS transistor.

10. The transistor circuit of claim 1, wherein the transistor circuit is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

11. A transistor circuit comprising:
first means for amplifying or switching comprising a silicon channel; and
second means for amplifying or switching comprising a silicon germanium channel.

12. The transistor circuit of claim 11, wherein the first means for amplifying or switching is a NMOS transistor and the silicon channel is a strained silicon channel.

13. The transistor circuit of claim 12, wherein the strained silicon channel is a tensile strained silicon channel.

14. The transistor circuit of claim 11, wherein the second means for amplifying or switching is a PMOS transistor and the silicon germanium channel is a strained channel.

15. The transistor circuit of claim 14, wherein the strained silicon germanium channel is a compressive strained silicon germanium channel.

16. The transistor circuit of claim 11, wherein the silicon channel is a strained silicon channel and the silicon germanium channel is a relaxed silicon germanium channel.

17. The transistor circuit of claim 11, wherein the silicon germanium channel is a on a 110 substrate.

18. The transistor circuit of claim 17, wherein the silicon germanium channel is a relaxed silicon germanium channel.

19. The transistor circuit of claim 11, wherein the first means for amplifying or switching is a NMOS transistor and the second means for amplifying or switching is a PMOS transistor.

20. The transistor circuit of claim 11, wherein the transistor circuit is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

21. A transistor circuit comprising:
a NMOS transistor comprising a silicon channel; and
a PMOS transistor comprising a silicon germanium channel.

22. The transistor circuit of claim 21, wherein the silicon channel is a strained silicon channel on a 100 substrate.

23. The transistor circuit of claim 22, wherein the strained silicon channel is a tensile strained silicon channel.

24. The transistor circuit of claim 21, wherein the silicon germanium channel is a strained channel on a 100 substrate.

25. The transistor circuit of claim 24, wherein the strained silicon germanium channel is a compressive strained silicon germanium channel.

26. The transistor circuit of claim 21, wherein the silicon channel is a strained silicon channel on a 110 substrate and the silicon germanium channel is a relaxed silicon germanium channel on a 110 substrate.

27. The transistor circuit of claim 21, wherein the transistor circuit is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

28. A method of manufacturing a transistor circuit, the method comprising:
providing a substrate;
forming a plurality of alternative epitaxial layers of silicon and silicon germanium;
forming a shallow trench insolation region;
forming a dummy gate;
depositing a gate spacer;
etching the gate spacer;
etching a PMOS region;
etching the silicon germanium layers to form recessed regions;
forming a plurality of spacers in the recessed regions;
forming a source region and a drain region for the PMOS region;
forming a NMOS spacer; and
forming a source region and a drain region for an NMOS region.

29. The method of claim 28, further comprising:
depositing a silicon nitride film before forming the shallow trench isolation region;
masking an NMOS region before etching the PMOS spacer; and
wherein the source region and the drain region for the PMOS region and the NMOS region are epitaxial grown.

30. The method of claim 28, further comprising incorporating the transistor circuit into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
